(19) United States
(12) Patent Application Publication
(10) Pub. No.: US 2007/0034988 A1
(43) Pub. Date: Feb. 15, 2007

(54) Metal-Insulator-Metal (MIM) Capacitors Formed Beneath First Level Metallization and Methods of Forming Same

(75) Inventors: Seok-Jun Won, Seoul (KR); Ju Youn Kim, Gyeonggi-do (KR); Min Woo Song, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/457,265

(22) Filed: Jul. 13, 2006

(30) Foreign Application Priority Data
Aug. 11, 2005 (KR) 2005-74006

(51) Int. Cl. H01L 29/00; H01L 23/48

(52) U.S. Cl. 257/532; 257/762

(57) ABSTRACT

A metal-insulator-metal (MIM) capacitor for an integrated circuit may be provided on the interlayer insulating layer and covered by a inter-metal dielectric (IMD) layer. This IMD layer has at least a first opening therein that exposes an upper surface of a first electrode of the MIM capacitor. This first opening is filled with a first copper damascene interconnect pattern, which may in some embodiments be part of a dual-damascene copper interconnect structure associated with a first and lowermost level of metallization (e.g., M1 wiring layer). This first copper damascene interconnect pattern may have an upper surface that is planar with an upper surface of the IMD layer and a bottom surface that is in contact with the upper surface of the first electrode of the MIM capacitor.

### REFERENCE TO PRIORITY APPLICATION

This application claims priority to Korean Patent Application No. 2005-74006, filed Aug. 11, 2005, the disclosure of which is hereby incorporated herein by reference.

### FIELD OF THE INVENTION

The present invention relates to integrated circuit capacitors and, more particularly, to metal-insulator-metal (MIM) capacitors and methods of forming MIM capacitors.

### BACKGROUND OF THE INVENTION

Integrated circuit capacitors include metal-oxide-semiconductor (MOS) capacitors, P-N junction capacitors, polySi-insulator-polySi (PIP) capacitors and metal-insulator-metal (MIM) capacitors. Of these types of capacitors, MIM capacitors offer enhanced characteristics because single crystal silicon electrodes and polysilicon electrodes typically have higher resistance compared to metal electrodes. Moreover, the biasing of silicon electrodes, including single crystal silicon and poly-Si electrodes, can cause the formation of depletion regions therein that cause capacitance variations, which are a function of applied voltage. Accordingly, MIM capacitors have frequently been utilized on integrated circuit substrates in order to achieve improved capacitance characteristics and greater capacitance stability, which typically results in lower frequency dependence. In view of these preferred characteristics, MIM capacitors have frequently been used in many analog devices, system-on-chip (SOC) devices and mixed mode signal applications Some of these applications include CMOS image sensors, LCD drivers and RF filters. Unfortunately, efforts to improve MIM capacitor performance using heat treatment may cause metal electrode oxidation, which can lower MIM capacitance.

Prior art MIM capacitors are frequently formed as type-1 or type-2 MIM capacitors. Type-1 MIM capacitors includes a lower capacitor electrode and an upper capacitor electrode formed between a first level of metallization (e.g., M1 level) and a second level of metallization (e.g., M2 level). In particular, a type-1 MIM capacitor includes a lower capacitor electrode, a capacitor dielectric layer and an upper capacitor electrode, which are formed on an underlying electrically insulating layer having a layer of interconnect metallization therein. A capping layer of silicon nitride may extend between the underlying electrically insulating layer and the lower capacitor electrode. A layer of electrically insulating material may also extend between the upper capacitor electrode and a second level of metallization. Respective first and second interconnect patterns associated with this second level of metallization may be electrically connected by respective vias to the underlying lower and upper capacitor electrodes. In contrast, a type-2 MIM capacitor includes a lower capacitor electrode formed as a first metallization layer pattern (e.g., copper pattern) and a capacitor dielectric layer and upper capacitor electrode formed on the lower capacitor electrode. A layer of electrically insulating material may also extend between the upper capacitor electrode and a second level of metallization. Respective first and second interconnect patterns associated with this second level of metallization may be electrically connected by respective vias to the underlying lower and upper capacitor electrodes.

### SUMMARY OF THE INVENTION

Embodiments of the present invention include methods of forming metal-insulator-metal (MIM) capacitors on integrated circuit substrates having damascene (e.g., dual-damascene) wiring patterns therein, and integrated circuits formed thereby. According to some of these embodiments, an integrated circuit device includes a semiconductor substrate having active devices (e.g., transistors) therein and an interlayer insulating layer on the semiconductor substrate. A MIM capacitor is provided on the interlayer insulating layer and an inter-metal dielectric (IMD) layer is provided, which covers the MIM capacitor. This IMD layer has at least a first opening therein that exposes an upper surface of a first electrode of the MIM capacitor. This first opening is filled with a first copper damascene interconnect pattern, which may in some embodiments be part of a dual-damascene copper interconnect structure associated with a first and lowermost level of metallization (e.g., M1 wiring layer). This first copper damascene interconnect pattern may have an upper surface that is planar with an upper surface of the IMD layer and a bottom surface that is in contact with the upper surface of the first electrode of the MIM capacitor. According to further aspects of these embodiments, the IMD layer has a second opening therein that exposes an upper surface of a second electrode of the MIM capacitor. This second opening is filled with a second copper damascene interconnect pattern. This second copper damascene interconnect pattern may have a bottom surface in contact with the upper surface of the second electrode of the MIM capacitor and an upper surface that is planar with the upper surface of the IMD layer.

According to additional embodiments of the invention, the semiconductor substrate may include a semiconductor region of first conductivity type therein and the second electrode of the MIM capacitor may be electrically connected to the semiconductor region. In this embodiment, the interlayer insulating layer may have a via opening therein filled with an electrically conductive via and the second electrode of the MIM capacitor is electrically connected to the semiconductor region by the electrically conductive via. This electrically conductive via may be formed of tungsten in some embodiments.

According to further aspects of these embodiments of the invention, the first electrode of the MIM capacitor includes a material selected from a group consisting of Ti, TiN, Ta, TaN, W, WN, Pt, Ir, Ru, Rh, Os, Pd and Al. The MIM capacitor may also include a capacitor dielectric layer selected from a group consisting of SiOₓ, SiₓN_{y}, SiₓC_{y}, SiₓO_{y}N_{z}, SiₓO_{y}C_{z}, AlₓO_{y}, HfₓO_{y} and TaₓO_{y} and combinations thereof.

Still further embodiments of the present invention include methods of forming an integrated circuit device by forming a metal-insulator-metal (MIM) capacitor on an integrated circuit substrate and forming an inter-metal dielectric (IMD) layer on the MIM capacitor. The IMD layer is then patterned to define a first opening therein that exposes an upper surface of a first electrode of the MIM capacitor. A first copper interconnect pattern is formed in the first opening using a copper damascene process. In some of these embodiments, the first copper interconnect pattern may be part of a dual-damascene interconnect structure associated with a lowermost level of copper metallization (e.g., M1 wiring layer). In further embodiments, the step of forming an inter-metal dielectric layer is preceded by a step of heat treating a dielectric layer of the MIM capacitor at a temperature in a range from about 300° C. to about 500° C. This heat treatment, which may be performed in an oxidizing ambient (e.g., an oxygen containing plasma), is performed for a sufficient duration to improve the leakage current characteristics of the capacitor dielectric within the MIM capacitor. The heat treatment may also be performed for a sufficient duration to increase a dielectric constant of the capacitor dielectric within the MIM capacitor.

According to further aspects of these method embodiments, the step of forming a first copper interconnect pattern in the first opening using a copper damascene process includes the steps of depositing a copper seed layer in the first opening and electroplating a copper interconnect layer onto the copper seed layer within the first opening. Thereafter, the copper interconnect layer is planarized for a sufficient duration to expose the IMD layer. These embodiments may also include forming an interlayer insulating layer on the integrated circuit substrate before forming a metal-insulator-metal (MIM) capacitor. The MIM capacitor is then formed on the interlayer insulating layer (e.g., interlayer dielectric layer (ILD)).

According to further aspects of these embodiments, the step of forming a metal-insulator-metal (MIM) capacitor includes the steps of sequentially depositing a first metal layer, a capacitor dielectric layer and a second metal layer on the interlayer insulating layer and then selectively patterning the second metal layer to define an upper capacitor electrode. The first metal layer may also be selectively patterned to define a lower capacitor electrode. The first and second metal layers may be formed of metals selected from a group consisting of Ti, TiN, Ta, TaN, W, WN, Pt, Ir, Ru, Rh, Os, Pd and Al, and the capacitor dielectric layer may be selected from a group consisting of SiOₓ, SiₓN_{y}, SiₓC_{y}, SiₓO_{y}N_{z}, SiₓO_{y}C_{z}, AlₓO_{y}, HfₓO_{y} and TaₓO_{y} and combinations thereof.

### BRIEF DESCRIPTION OF THE DRAWINGS

FIG. 1A is a plan layout view of an integrated circuit capacitor according to an embodiment of the present invention.

FIG. 1B is a cross-sectional view of an integrated circuit capacitor of FIG. 1A taken along the line A-A′, according to an embodiment of the present invention.

FIG. 1C is a cross-sectional view of another integrated circuit capacitor of FIG. 1A taken along the line A-A′, according to an embodiment of the present invention.

FIG. 2A is a plan layout view of an integrated circuit capacitor according to an embodiment of the present invention.

FIG. 2B is a cross-sectional view of an integrated circuit capacitor of FIG. 2A taken along line A-A′, according to an embodiment of the present invention.

FIG. 3A is a plan layout view of an integrated circuit capacitor according to an embodiment of the present invention.

FIG. 3B is a cross-sectional view of an integrated circuit capacitor of FIG. 3A taken along line A-A′, according to an embodiment of the present invention.

FIGS. 4A-4E are cross-sectional views of intermediate structures that illustrate methods of forming the integrated circuit capacitors of FIGS. 1A-1C, according to embodiments of the present invention.

FIGS. 5A-5C are cross-sectional views of intermediate structures that illustrate methods of forming the integrated circuit capacitors of FIGS. 3A-3B, according to embodiments of the present invention.

### DETAILED DESCRIPTION OF PREFERRED EMBODIMENTS

The present invention now will be described more fully herein with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. Like reference numerals refer to like elements throughout.

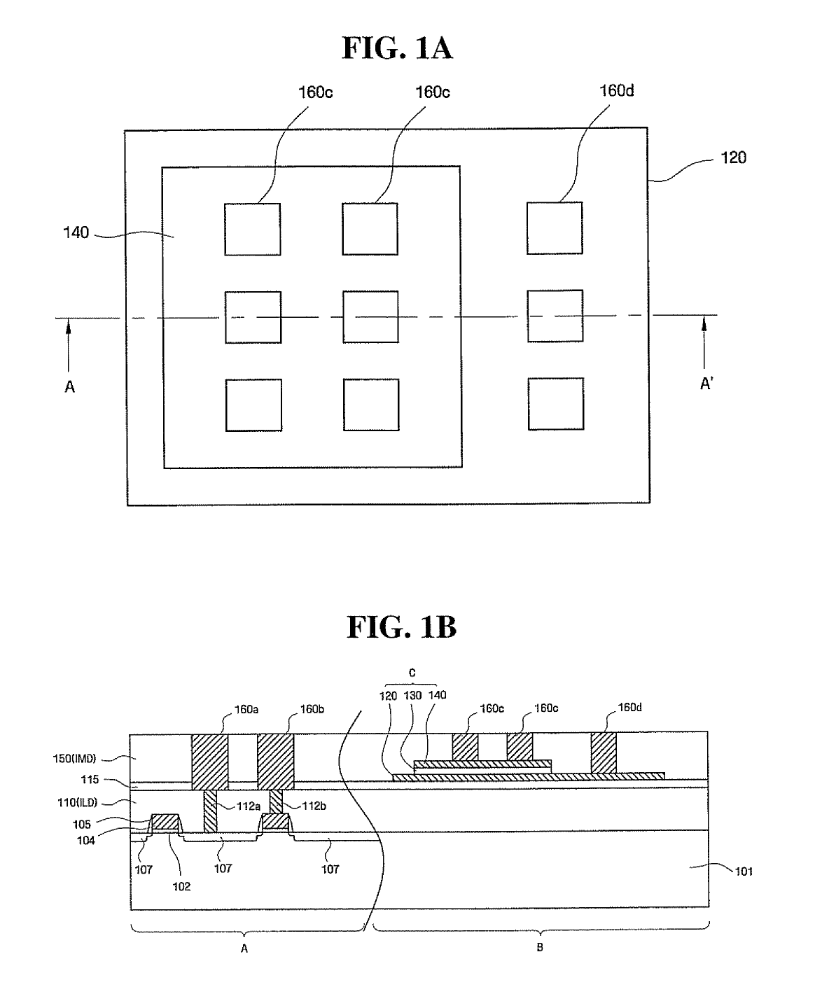

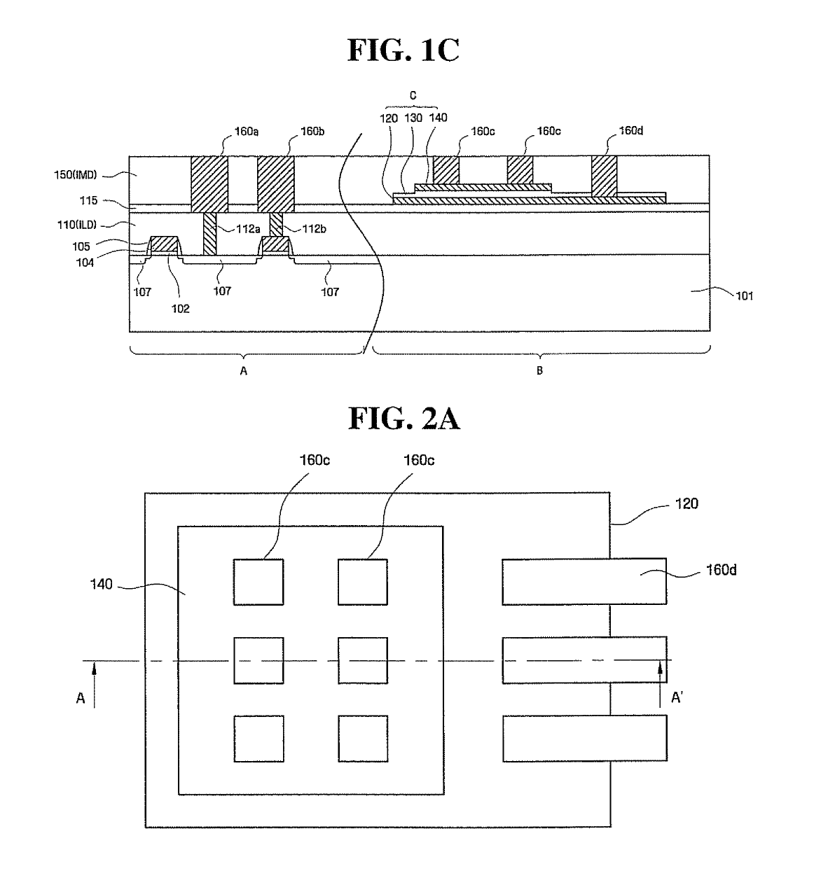

Referring now to FIG. 1A, an integrated circuit capacitor according to a first embodiment of the invention is illustrated as including a lower capacitor electrode 120, an upper capacitor electrode 140 and a plurality of copper damascene interconnect patterns 160c and 106d, which are electrically connected to the upper and lower capacitor electrodes 140 and 120, respectively. As illustrated by FIGS. 1B and 1C, an integrated circuit chip may include a first semiconductor region A and a second semiconductor region B therein. The first semiconductor region A may be a memory cell array region of an integrated circuit memory device and the second region B may be a peripheral circuit region. The first semiconductor region A is shown as including active devices therein. These active devices (e.g., MOS transistors) include insulated gate electrodes (regions 102, 104) with sidewall insulating spacers 105, and source/drain regions 107 of first conductivity type (e.g., N-type) within a semiconductor substrate 101. An interlayer dielectric (ILD) layer 110 (e.g., a silicon dioxide insulating layer) is provided on the active devices and an electrically insulating capping layer 115 is provided on the ILD layer 110. This capping layer 115 may be a silicon nitride layer. Conductive vias 112a and 112b extend through the ILD layer 110. These conductive vias 112a and 112b are electrically connected to the source/drain region 107 and gate electrode 104, respectively. These conductive vias 112a may be formed of tungsten (W) metal.

The metal-insulator-metal (MIM) capacitor (C) is illustrated as being formed directly on the capping layer 115. The MIM capacitor includes a lower capacitor electrode 120, an upper capacitor electrode 140 and a capacitor dielectric layer 130 extending between the upper and lower capacitor electrodes. The lower and upper capacitor electrodes may be formed of a material selected from a group consisting of Ti, TiN, Ta, TaN, W, WN, Pt, Ir, Ru, Rh, Os, Pd and Al and the capacitor dielectric layer may be formed of a dielectric selected from a group consisting of SiOₓ, SiₓN_{y}, SiₓC_{y}, SiₓO_{y}N_{z}, SiₓO_{y}C_{z}, AlₓO_{y}, HfₓO_{y} and TaₓO_{y} and combinations thereof.

This capacitor dielectric layer 130 may be patterned to have an equivalent dimension vis-a-vis the upper capacitor electrode 140, as illustrated by FIG. 1B, or may have an equivalent dimension vis-a-vis the lower capacitor electrode 120, as illustrated by FIG. 1C. An inter-metal dielectric (IMD) layer 150 is provided directly on the capping layer 115. This IMD layer 150 extends beneath a lowermost level of metallization (e.g., M1 layer of metallization). A plurality of interconnect vias are provided that extend through the IMD layer 150 and capping layer 115. As described more fully hereinbelow, these interconnect vias are illustrated as copper damascene interconnect patterns 160a-160d.

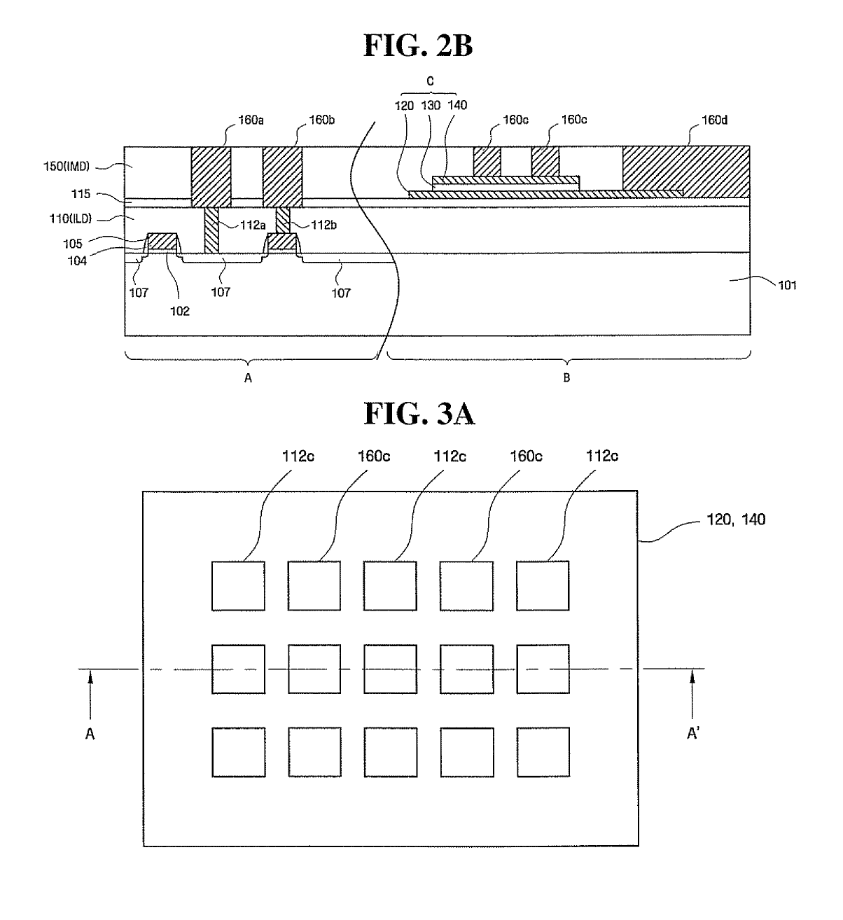

Referring now to FIGS. 2A-2B, an integrated circuit capacitor according to a second embodiment of the invention is illustrated as including a lower capacitor electrode 120, an upper capacitor electrode 140 and a plurality of copper damascene interconnect patterns 160c and 106d, which are electrically connected to the upper and lower capacitor electrodes 140 and 120, respectively. The interconnect patterns 160d illustrated in FIGS. 2A-2B are of larger dimension relative to the interconnect patterns 160d illustrated by FIGS. 1A-1C. As illustrated by FIG. 2B, an integrated circuit chip may include a first semiconductor region A and a second semiconductor region B therein. The first semiconductor region A may be a memory cell array region of an integrated circuit memory device and the second region B may be a peripheral circuit region. The first semiconductor region A is shown as including active devices therein. These active devices (e.g., MOS transistors) include insulated gate electrodes (regions 102, 104) with sidewall insulating spacers 105, and source/drain regions 107 of first conductivity type (e.g., N-type) within a semiconductor substrate 101. An interlayer dielectric (ILD) layer 110 (e.g., a silicon dioxide insulating layer) is provided on the active devices and an electrically insulating capping layer 115 is provided on the ILD layer 110. This capping layer 115 may be a silicon nitride layer. Conductive vias 112a and 112b extend through the ILD layer 110. These conductive vias 112a and 112b are electrically connected to the source/drain region 107 and gate electrode 104, respectively. The metal-insulator-metal (MIM) capacitor (C) is illustrated as being formed directly on the capping layer 115. The MIM capacitor includes a lower capacitor electrode 120, an upper capacitor electrode 140 and a capacitor dielectric layer 130 extending between the upper and lower capacitor electrodes. An inter-metal dielectric (IMD) layer 150 is provided directly on the capping layer 115. This IMD layer 150 extends beneath a lowermost level of metallization (e.g., M1 layer of metallization). A plurality of interconnect vias are provided that extend through the IMD layer 150 and capping layer 115. As described more fully hereinbelow, these interconnect vias are illustrated as copper damascene interconnect patterns 160a-160d.

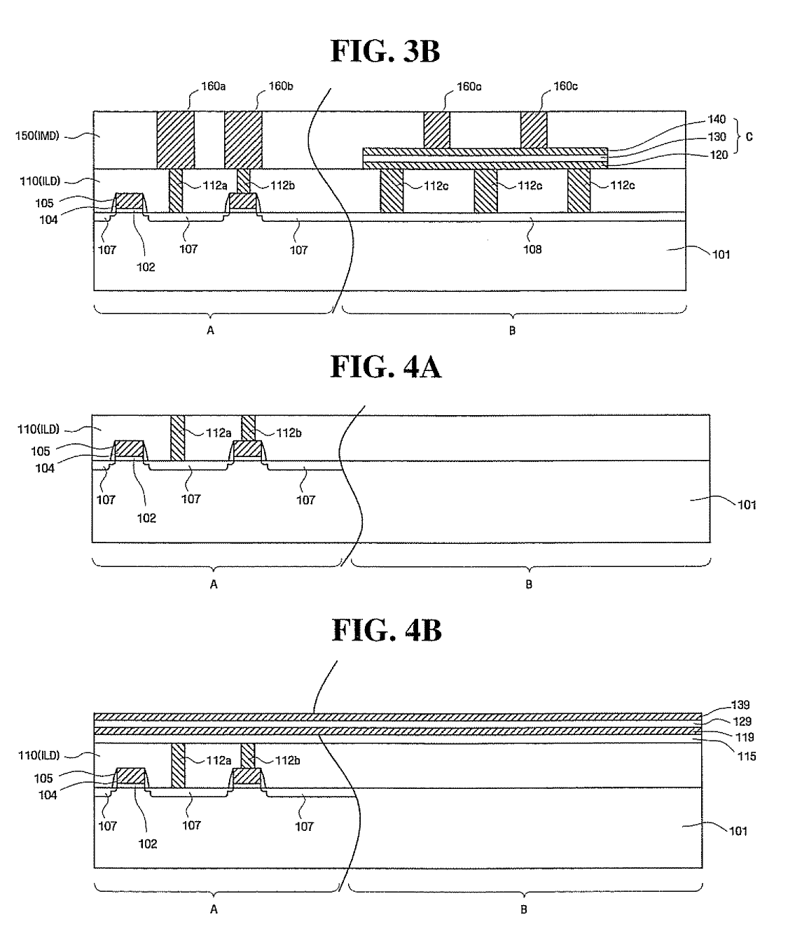

Referring now to FIGS. 3A-3B, an integrated circuit capacitor according to a third embodiment of the invention is illustrated as including a lower capacitor electrode 120 and an upper capacitor electrode 140 of equivalent dimension. In addition, a semiconductor region 108 of first conductivity type is provided in the substrate 101 and a plurality of electrically conductive vias 112c (e.g., tungsten vias) are provided to electrically connect the semiconductor region 108 to the lower capacitor electrode 120. These vias 112a are provided within openings in the interlayer dielectric layer 110, as illustrated. Based on this configuration, the application of a potential bias (e.g., voltage) to the semiconductor region 108 will be transferred to the lower capacitor electrode 120.

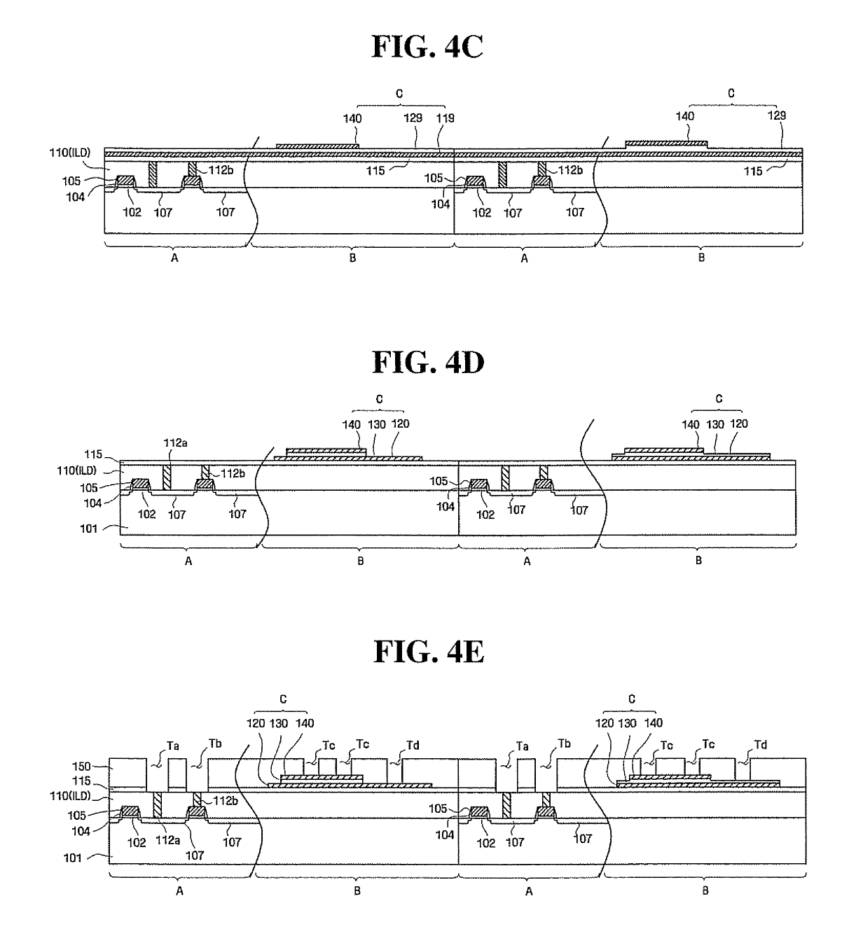

Referring now to FIGS. 4A-4E, methods of forming the integrated circuit capacitors of FIGS. 1A-1C include forming a plurality of MOS transistors in a memory cell region A of an integrated circuit substrate 101. These MOS transistors are illustrated as including insulated gate electrodes (regions 102, 104 and 105) and source/drain regions 107. An interlayer dielectric layer (ILD) 110, which covers the MOS transistors, is deposited on the substrate 101. This ILD layer 110 may be an oxide layer having a thickness in a range from about 2,000 Å to about 20,000 Å. This ILD layer 110 may be patterned to define a plurality of openings therein, which are subsequently filled with conductive vias 112a and 112b using conventional techniques. As illustrated by FIG. 4B, an electrically insulating capping layer 115 may be deposited on the ILD layer 110. This capping layer 115 may be a silicon nitride layer having a thickness in a range from about 10 Å to about 1,000 Å. Thereafter, a lower metal electrode layer 119, a capacitor dielectric layer 129 and an upper metal electrode layer 139 are deposited on the capping layer 115. The lower and upper metal electrode layers 119 and 139 may have a thickness in a range from about 500 Å to about 1,000 Å. The lower and upper metal electrode layers may be formed of a material selected from a group consisting of Ti, TiN, Ta, TaN, W, WN, Pt, Ir, Ru, Rh, Os, Pd and Al. The capacitor dielectric layer 129 may have a thickness in a range from about 200 Å to about 700 Å. The capacitor dielectric layer may be formed of SiOₓ, SiₓN_{y}, SiₓC_{y}, SiₓO_{y}N_{z}, SiₓO_{y}C_{z}, AlₓO_{y}, HfₓO_{y} and TaₓO_{y} and combinations thereof.

Thereafter, as illustrated by FIG. 4C, a photolithographically defined patterning step may be performed on the upper metal electrode layer 139 to define an upper capacitor electrode 140. The regions A and B on the left side of FIGS. 4C-4E correspond to the capacitor of FIG. 1 B and the regions A and B on the right side of FIGS. 4C-4E correspond to the capacitor of FIG. 1C. With respect to FIG. 4D, the capacitor dielectric layer 129 is patterned to define a patterned capacitor dielectric layer 130. The lower metal electrode layer 119 is also patterned to define a lower capacitor electrode 120.

According to further aspects of these embodiments, the capacitor dielectric layer 129 (or patterned capacitor dielectric layer 130) may be heat treated in an oxidizing ambient at a temperature in a range from about 300° C. to about 500° C. This heat treatment may be performed by exposing the MIM capacitor to an oxygen containing plasma having a temperature in the range from about 300° C. to about 500° C. As illustrated by FIG. 4E, an intermetal dielectric layer 150 is deposited on the structure of FIG. 4D and then patterned to define a plurality of openings (Ta, Tb, Tc and Td) therein. These openings are then filled with copper damascene interconnect patterns 160a-160d. The formation of the copper damascene interconnect patterns may include depositing a layer of copper into the openings and then planarizing the deposited layer of copper. This deposition step may be performed as a chemical vapor deposition (CVD). Alternatively, the layer of copper may be deposited by depositing a copper seed layer into the openings and then electroplating a copper interconnect layer onto the seed layer. Thereafter, the copper interconnect layer is planarized (e.g., by chemical-mechanical polishing (CMP)).

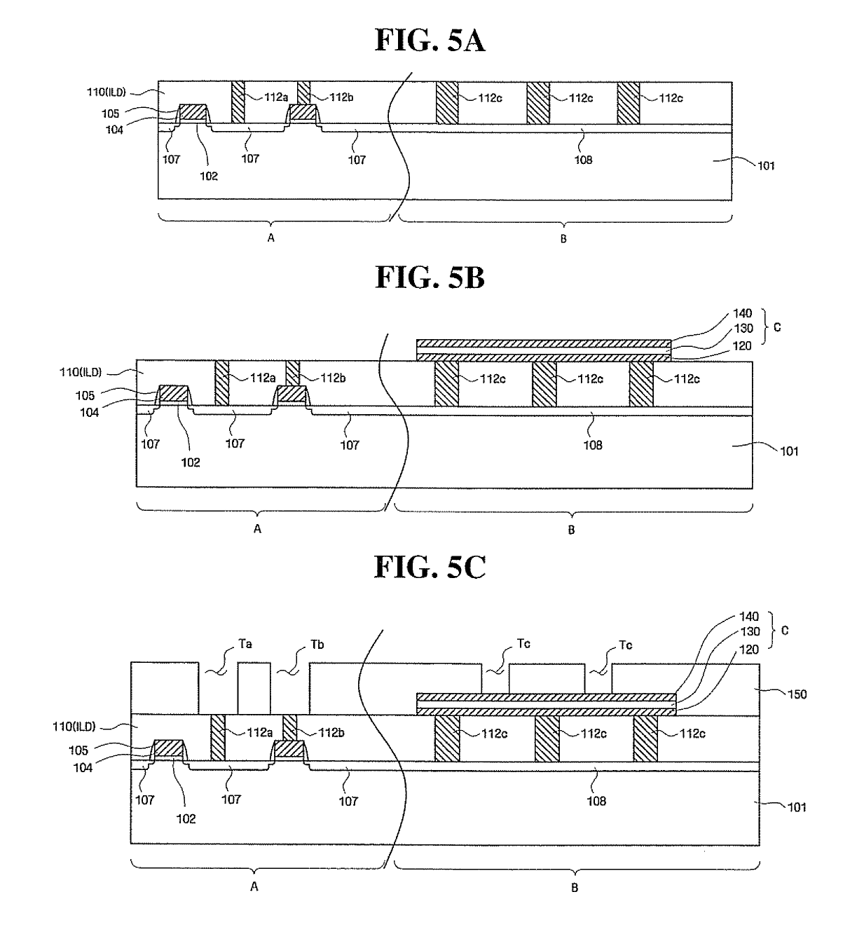

Methods of forming MIM capacitors according to additional embodiments of the invention are illustrated by FIGS. 5A-5C. These embodiments include forming a plurality of MOS transistors in a memory cell region A of an integrated circuit substrate 101. These MOS transistors are illustrated as including insulated gate electrodes (regions 102, 104 and 105) and source/drain regions 107. An interlayer dielectric layer (ILD) 110, which covers the MOS transistors, is deposited on the substrate 101. This ILD layer 110 may be an oxide layer having a thickness in a range from about 2,000 Å to about 20,000 Å. This ILD layer 110 may be patterned to define a plurality of openings therein, which are subsequently filled with conductive vias 112a-112c using conventional techniques. As illustrated by FIG. 5B, a MIM capacitor C is formed on the ILD layer 110. This MIM capacitor includes a lower capacitor electrode 120, a capacitor dielectric layer 130 and an upper capacitor electrode 140. The capacitor dielectric layer 130 may undergo the above-described heat treatment in an oxidizing ambient. This MIM capacitor is covered by an inter-metal dielectric layer 150, which is subsequently patterned to define a plurality of openings (Ta, Tb and Tc) therein. These openings are filled as described above with respect to FIG. 4E.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. An integrated circuit device, comprising:
a semiconductor substrate having active devices therein;
an interlayer insulating layer on said semiconductor substrate;
a metal-insulator-metal (MIM) capacitor on said interlayer insulating layer;
an inter-metal dielectric (IMD) layer on said MIM capacitor, said IMD layer having a first opening therein that exposes an upper surface of a first electrode of said MIM capacitor; and
a first copper damascene interconnect pattern in the first opening, said first copper damascene interconnect pattern configured as a lowermost layer of copper metallization on said semiconductor substrate and having an upper surface that is planar with an upper surface of said IMD layer.

2. The device of claim 1, wherein said first copper damascene interconnect pattern has a bottom surface in contact with the upper surface of the first electrode of said MIM capacitor.

3. The device of claim 1, wherein said IMD layer has a second opening therein that exposes an upper surface of a second electrode of said MIM capacitor.

4. The device of claim 3, further comprising a second copper damascene interconnect pattern extending in the second opening and having a bottom surface in contact with the upper surface of the second electrode of said MIM capacitor.

5. The device of claim 4, wherein said second copper damascene interconnect pattern has an upper surface that is planar with an upper surface of said IMD layer.

6. The device of claim 1, wherein said semiconductor substrate comprises a semiconductor region of first conductivity type therein; and
wherein a second electrode of said MIM capacitor is electrically connected to the semiconductor region.

7. The device of claim 6, wherein said interlayer insulating layer has a via opening therein filled with an electrically conductive via; and wherein the second electrode of said MIM capacitor is electrically connected to the semiconductor region by the electrically conductive via.

8. The device of claim 7, wherein the electrically conductive via comprises tungsten.

9. The device of claim 1, wherein the first electrode of said MIM capacitor comprises a material selected from a group consisting of Ti, TiN, Ta, TaN, W, WN, Pt, Ir, Ru, Rh, Os, Pd and Al.

10. The device of claim 1, wherein said MIM capacitor comprises a dielectric layer selected from a group consisting of SiOₓ, SiₓN_{y}, SiₓC_{y}, SiₓO_{y}N_{z}, SiₓO_{y}C_{z, Al}ₓO_{y}, HfₓO_{y} and TaₓO_{y} and combinations thereof.

11. A method of forming an integrated circuit device, comprising the steps of:
forming a metal-insulator-metal (MIM) capacitor on an integrated circuit substrate;
forming an inter-metal dielectric (IMD) layer on the MIM capacitor;
patterning the IMD layer to define a first opening therein that exposes an upper surface of a first electrode of the MIM capacitor; and
forming a first copper interconnect pattern as a lowermost layer of copper metallization on the semiconductor substrate by forming the first copper interconnect pattern in the first opening using a copper damascene process.

12. The method of claim 11, wherein said step of forming an inter-metal dielectric layer is preceded by a step of heat treating a dielectric layer of the MIM capacitor at a temperature in a range from about 300° C. to about 500° C.

13. The method of claim 11, wherein said step of forming a first copper interconnect pattern is preceded by a step of heat treating a dielectric layer of the MIM capacitor at a temperature in a range from about 300° C. to about 500° C.

14. The method of claim 11, wherein said step of forming an inter-metal dielectric layer is preceded by a step of heat treating the MIM capacitor in an oxidizing ambient.

15. The method of claim 14, wherein said step of heat treating comprises exposing the MIM capacitor to an oxygen containing plasma.

16. The method of claim 14, wherein said step of heat treating comprises exposing the MIM capacitor to an oxygen containing plasma having a temperature in a range from about 300° C. to about 500° C.

17. The method of claim 11, wherein said step of forming a first copper interconnect pattern in the first opening using a copper damascene process comprises depositing copper into the first opening by chemical vapor deposition.

18. The method of claim 11, wherein said step of forming a first copper interconnect pattern in the first opening using a copper damascene process comprises the steps of:
depositing a copper seed layer in the first opening;
electroplating a copper interconnect layer onto the copper seed layer within the first opening; and
planarizing the copper interconnect layer for a sufficient duration to expose the IMD layer.

19. The method of claim 11, wherein said step of patterning the IMD layer is preceded by a step of chemically-mechanically polishing the IMD layer to define a planar upper surface thereon.

20. The method of claim 11 wherein said step of forming a metal-insulator-metal (MIM) capacitor is preceded by a step of forming an interlayer insulating layer on the integrated circuit substrate; and wherein the MIM capacitor is formed on the interlayer insulating layer.

21. The method of claim 20, wherein said step of forming a metal-insulator-metal (MIM) capacitor comprises the steps of:
sequentially depositing a first metal layer, a capacitor dielectric layer and a second metal layer on the interlayer insulating layer;
selectively patterning the second metal layer to define an upper capacitor electrode; and
selectively patterning the first metal layer to define a lower capacitor electrode.

22. The method of claim 21, wherein each of the first and second metal layers comprises a material selected from a group consisting of Ti, TiN, Ta, TaN, W, WN, Pt, Ir, Ru, Rh, Os, Pd and Al.

23. The method of claim 22, wherein the capacitor dielectric layer is selected from a group consisting of SiOₓ, SiₓN_{y}, SiₓC_{y}, SiₓO_{y}N_{z}, SiₓO_{y}C_{z}, AlₓO_{y}, HfₓO_{y} and TaₓO_{y} and combinations thereof.
